(19) United States
(12) Patent Application Publication
(10) Pub. No.: US 2025/0151469 A1
(43) Pub. Date: May 8, 2025

(54) MICRO SEMICONDUCTOR LIGHT-EMITTING DIODE STRUCTURE AND METHOD FOR PRODUCING THE SAME

(71) Applicant: ams-OSRAM International GmbH, Regensburg (DE)

(72) Inventors: Alvaro Gomez-Iglesias, Regensburg (DE); Norwin von Malm, Nittendorf (DE); Stefan Heckelmann, Rieneck (DE); Harald König, Bernhardswald (DE)

(21) Appl. No.: 18/838,157

(22) PCT Filed: Feb. 2, 2023
(86) PCT No.: PCT/EP2023/052543

§ 371 Date: Aug. 13, 2024

(30) Foreign Application Priority Data
Feb. 17, 2022 (DE) 10 2022 103 763.0

(51) Int. Cl. H10H 20/819; H10H 20/01; H10H 20/815; H10H 20/824

(52) U.S. Cl. CPC H10H 20/819; H10H 20/013; H10H 20/017; H10H 20/815; H10H 20/824

(57) ABSTRACT

In an embodiment a micro semiconductor LED structure includes a first semiconductor layer of a first conductivity type, a second semiconductor layer of a second conductivity type, which is arranged on the first semiconductor layer, an active layer sequence including a first edge layer of the first conductivity type facing the first semiconductor layer and a second edge layer of the second conductivity type facing away from the first semiconductor layer and a third semiconductor layer of the second conductivity type, which is arranged at least on the active layer sequence, wherein the second semiconductor layer has at least one window, which penetrates through the second semiconductor layer from a side of the second semiconductor layer facing away from the first semiconductor layer toward the first semiconductor layer, wherein the first semiconductor layer has a recess in a region of the window, and wherein the active layer sequence is arranged at least in the recess.

### CROSS-REFERENCE TO RELATED APPLICATIONS

This patent application is a national phase filing under section 371 of PCT/EP2023/052543, filed Feb. 2, 2023, which claims the priority of German patent application 102022103763.0, filed Feb. 17, 2022, each of which is incorporated herein by reference in its entirety.

### TECHNICAL FIELD

A micro semiconductor light-emitting diode structure (hereinafter “micro semiconductor LED structure”) is provided. Furthermore, a method for producing a micro semiconductor LED structure is provided.

### SUMMARY

Embodiments provide a micro semiconductor LED structure having a structure size (for example this typically refers to the individual chip edge length or, in case of a dense array, to the pixel pitch) of less than 100 μm, in particular having a structure size in the single-digit μm range, i.e. less than 10 μm. Such small semiconductor LED structures are used in particular in so-called pixelated μLEDs.

Further embodiments provide a method for producing such a micro semiconductor LED structure.

According to at least one embodiment, a micro semiconductor LED structure described herein comprises a first semiconductor layer of a first conductivity type, a second semiconductor layer of a second conductivity type, which is arranged on the first semiconductor layer, an active layer sequence, and a third semiconductor layer of the second conductivity type.

The first semiconductor layer of the first conductivity type and the second and third semiconductor layers of the second conductivity type are oppositely doped. In other words, the respective semiconductor materials of the first semiconductor layer and of the second and third semiconductor layers are oppositely doped. For example, the first conductivity type is formed by n-doping the respective semiconductor material, and the second conductivity type is formed by p-doping the respective semiconductor material, or vice versa.

The active layer sequence comprises a first edge layer facing the first semiconductor layer and a second edge layer facing away from the first semiconductor layer. For example, the first edge layer is of the first conductivity type and the second edge layer is of the second conductivity type. For example, the first conductivity type is formed by n-doping the respective semiconductor material, and the second conductivity type is formed by p-doping the respective semiconductor material, or vice versa. Alternatively, for example, the first and the second edge layers may be intentionally left undoped. The edge layers can also be called outer barrier layers.

For example, a region configured to generate electromagnetic radiation, in particular visible light, of the active layer sequence between the first edge layer and the second edge layer has at least one pn junction, at least one single quantum well structure, and/or at least one multiple quantum well structure. The pn junction, the single quantum well structure or the multiple quantum well structure is configured to generate electromagnetic radiation.

The third semiconductor layer is at least partially arranged on the active layer sequence.

The second semiconductor layer has at least one window toward the first semiconductor layer. The second semiconductor layer has a first main surface facing the first semiconductor layer and a second main surface facing away from the first semiconductor layer. The window completely penetrates the second semiconductor layer from its second main surface toward its first main surface, so that the first semiconductor layer is free of the second semiconductor layer in the region of the window.

The first semiconductor layer has a recess in the region of the window. The active layer sequence is arranged at least in the recess. The first edge layer is electrically conductively connected to the first semiconductor layer in the recess. The third semiconductor layer is arranged on the active layer sequence at least in the region of the window. The second edge layer is electrically conductively connected to the third semiconductor layer.

In a micro semiconductor LED structure described herein, a radiation-generating region of the active layer sequence, when the micro LED structure is driven by an operating current, is, for example, at least substantially, confined to the recess. In particular, the radiation-generating region of the active layer sequence is, at least substantially, confined to the cross-section of the recess lying along the bottom surface of the recess. In plan view of the active layer sequence outer parts of the active layer sequence around the radiation-generating region lying between the radiation-generating region of the active layer sequence and mesa edges of the micro semiconductor LED structure are embedded between the second and the third semiconductor layers, that is between two semiconductor layers of the second conductivity type. This implies that an operating current only flows through the central radiation-generating region. Furthermore, the identical doping type of the second and third semiconductor layers reduces a risk of the opposite type charge carriers injected into the radiation-generating region diffusing laterally.

According to at least one embodiment of the micro semiconductor LED structure, at least one buffer layer is arranged at least in the region of the recess between the active layer sequence, in particular between the first edge layer of the active layer sequence, and the first semiconductor layer. The buffer layer serves, for example, to qualitatively increase a growth surface for the growth of the subsequent semiconductor layers, i.e. the active layer sequence, in particular to increase the crystal quality at the growth surface.

According to at least one embodiment of the micro semiconductor LED structure or its embodiment described above, flanks of the recess and the window extend obliquely to a main extension plane of the first semiconductor layer, such that the recess and the window widen in the direction away from the first semiconductor layer.

According to at least one other embodiment of the micro semiconductor LED structure or its embodiment first described above, flanks of the recess and the window extend substantially perpendicular to a main extension plane of the first semiconductor layer.

The expression “substantially perpendicular” means in the present context that the angle of the flanks to the main extension direction of the first semiconductor layer may deviate from exactly 90 degrees within the scope of the usual manufacturing tolerances familiar to the skilled person. In other words, the flanks are intended to be nominally perpendicular to the main extension plane of the first semiconductor layer, but may have an angle to the main extension direction of the first semiconductor layer that deviates slightly from 90 degrees within the scope of practically existing manufacturing tolerances.

According to at least one embodiment of the micro semiconductor LED structure or its embodiments described above, the flanks of the recess and the window are substantially free of the active layer sequence. In other words, the active layer sequence is present substantially only on a bottom surface of the recess of the first semiconductor layer.

According to at least one other embodiment of the micro semiconductor LED structure or its embodiments described above, the active layer sequence extends, starting from the bottom surface of the recess, over the flanks of the recess and the window to a side of the second semiconductor layer facing away from the first semiconductor layer. Accordingly, a micro semiconductor LED structure according to this embodiment comprises a first semiconductor layer of a first conductivity type, a second semiconductor layer of a second conductivity type arranged on the first semiconductor layer, an active layer sequence arranged on the first and second semiconductor layers, and a third semiconductor layer of the second conductivity type arranged on the active layer sequence. The active layer sequence is arranged substantially, except for a radiation-generating region, on a main surface of the second semiconductor layer facing away from the first semiconductor layer. In the region of the radiation-generating region, the active layer sequence penetrates through the second semiconductor layer toward the first semiconductor layer, penetrates into the first semiconductor layer there, and is electrically connected there with the first edge layer of the first conductivity type to the first semiconductor layer. The region in which the first edge layer is electrically conductively connected to the first semiconductor layer essentially defines the radiation-generating region of the active layer sequence. A second edge layer of the active layer sequence adjacent to the third semiconductor layer is of the second conductivity type and is electrically conductively connected to the third semiconductor layer. Seen in plan view of the third semiconductor layer, the radiation-generating region is substantially completely surrounded by a radiation-inactive region. This is achieved in particular by arranging the active layer sequence around the radiation-generating region on the second semiconductor layer. The micro semiconductor LED structure thus has a reverse biased pn junction around the radiation-generating region between the second semiconductor layer and the first edge layer of the active layer sequence.

According to at least one embodiment of the preceding embodiment, a thickness of the active layer sequence in the region of the flanks is smaller than a thickness of the active layer sequence in the region along the bottom surface of the recess and in the region on the second semiconductor layer. In case of a multiple quantum well structure, this can imply, for example, a larger bandgap and can further impede lateral charge carrier transport, i.e., transport within the active layer sequence toward mesa surfaces of the micro semiconductor LED structure.

According to at least one embodiment of the micro semiconductor LED structure or its embodiments described above, at least the active layer sequence comprises a semiconductor material based on phosphide compound semiconductor material.

In the present context, “based on phosphide compound semiconductor material” means that the active layer sequence, or at least a part thereof, comprises (AlₙGa₁₋ₙ)₁₋ₘInₘP, where 0≤n≤1, 0≤m≤1. This material does not necessarily have to have a mathematically exact composition according to the above formula. Rather, it may include one or more dopants as well as additional constituents. For the sake of simplicity, however, the above formula contains only the essential constituents of the crystal lattice (Al, Ga, In, P), even if these may be partially replaced and/or supplemented by small amounts of other substances.

In principle, a micro semiconductor LED structure described here is also applicable to other semiconductor LED material systems. For example, it is applicable to micro semiconductor LED structures based on a nitride compound semiconductor material such as AlₙIn₁₋ₙ₋ₘGaₘN, where 0≤n≤1, 0≤m≤1 and n+m≤1. This material does not necessarily have to have a mathematically exact composition according to the above formula. Rather, it may include one or more dopants as well as additional constituents. For the sake of simplicity, however, the above formula contains only the essential constituents of the crystal lattice, i.e. Al, Ga, In, N, even if these may be partially replaced and/or supplemented by small amounts of other substances.

According to an embodiment of the micro semiconductor LED structure, the first semiconductor layer and the second semiconductor layer form a pn-junction. Preferably, the pn-junction formed by the first semiconductor layer and the second semiconductor layer surrounds the recess, preferably completely. In particular, the active layer sequence penetrates the first semiconductor layer and the second semiconductor layer and therefore the pn-junction in the recess completely. Preferably, in this embodiment the radiation generating region is arranged only on a bottom surface of the recess. In such a way, lateral carrier leakage from the active region can be at least reduced.

Particularly, the active semiconductor layer sequence is in direct contact with the first semiconductor layer within the recess. In particular, in the recess, the first edge layer is directly adjacent to the first semiconductor layer and the second edge layer is directly adjacent to the third semiconductor layer.

Particularly, the micro semiconductor LED structure comprises the following layer sequence consisting of the following layers in the mentioned order:
the first semiconductor layer of the first conductivity type
the second semiconductor layer of the second conductivity type arranged on the first semiconductor layer,
the active layer sequence, and
the third semiconductor layer of the second conductivity type.

According to an embodiment the micro semiconductor LED structure has an edge length of at most 100 micrometer.

The micro semiconductor LED structure is a micro-LED, for example. As a broad definition, a micro-LED could be seen as any light emitting diode (LED)—generally not a laser—with a particularly small size.

As a rule-and this is a very important criterion in addition to size—a growth substrate is removed from micro-LEDs, so that typical heights of such micro-LEDs are in the range of 1.5 micrometer to 10 micrometer, for example.

In principle, a micro-LED does not necessarily have to have a rectangular radiation emission surface. Generally, for example, an LED could have a radiation emission surface in which, in plan view on the first semiconductor layer and the second semiconductor layer, any lateral extent of the radiation emission surface is less than or equal to 100 micrometer or less than or equal to 70 micrometer.

For example, in the case of rectangular micro-LEDs, an edge length—especially in plan view of the layers of the layer stack—smaller than or equal to 70 micrometer or smaller than or equal to 50 micrometer is often cited as a criterion.

Mostly, such micro-LEDs are provided on wafers with—for the μLED non-destructively—detachable holding structures.

At present, micro-LEDs are mainly used in displays. The micro-LEDs form pixels or subpixels and emit light of a defined color. Small pixel size and a high density with close distances make micro-LEDs suitable, among others, for small monolithic displays for AR applications, especially data glasses. In addition, other applications are being developed, in particular regarding the use in data communication or pixelated lighting applications.

Different ways of spelling micro-LED, e.g. μLED, μ-LED, uLED, u-LED or micro light emitting diode can be found in the relevant literature.

According to at least one embodiment of a method described herein for producing at least one micro semiconductor LED structure, a first semiconductor layer of a first conductivity type is first provided.

A second semiconductor layer of a second conductivity type is later applied on the first semiconductor layer. The second semiconductor layer has a first main surface facing the first semiconductor layer and a second main surface facing away from the first semiconductor layer.

In the second semiconductor layer, a window is later introduced from the second main surface toward the first semiconductor layer, for example by means of conventional photolithography and subsequent conventional anisotropic etching, said window penetrating through the second semiconductor layer up to the first main surface, i.e. up to the first semiconductor layer.

A recess is later formed through the window into the first semiconductor layer, for example by means of anisotropic etching, in the region of the first semiconductor layer exposed by the window. The recess has a bottom surface and flanks. The flanks extend from the bottom surface of the recess to a main surface of the first semiconductor layer adjacent to the second semiconductor layer.

Later, an active layer sequence is applied through the window on the first semiconductor layer. The active layer sequence comprises a first edge layer of the first conductivity type facing the first semiconductor layer and a second edge layer of the second conductivity type facing away from the first semiconductor layer.

Later, a third semiconductor layer of the second conductivity type is applied on the active layer sequence.

According to at least one embodiment of the method or its aforementioned embodiment, a buffer layer is applied at least on a bottom surface of the recess. The active layer sequence is later applied on the buffer layer. The buffer layer is, for example, of the first conductivity type. The buffer layer serves, for example, to qualitatively increase a growth surface for the growth of the subsequent semiconductor layers, i.e. the active layer sequence, in particular to increase the crystal quality at the growth surface. Alternatively or in addition the growth surface can be precleaned before epitaxial growth at high temperature, e.g. by means of Hydrogen and/or ASH₃/PH₃.

According to at least one embodiment of the method, the first semiconductor layer, the buffer layer, if applicable, and the first edge layer are doped opposite to the second semiconductor layer, third semiconductor layer and second edge layer. For example, the first conductivity type is formed by n-doping the respective semiconductor material, and the second conductivity type is formed by p-doping the respective semiconductor material, or vice versa. For example, the first semiconductor layer, the buffer layer, if applicable, and the first edge layer are n-doped, and the second semiconductor layer, the third semiconductor layer, and the second edge layer are p-doped, or vice versa.

According to at least one embodiment of the method or its aforementioned embodiments, the window and the recess are provided with flanks extending substantially perpendicular to a main extension plane of the first semiconductor layer.

Later, the active layer sequence is applied on the first semiconductor layer substantially only at the bottom surface of the recess and on a second main surface of the second semiconductor layer facing away from the first semiconductor layer. The flanks remain substantially free of the active layer sequence. The steepness of the flanks can be adjusted, for example, by a suitable choice of parameters during anisotropic etching.

The expression “substantially free of the active layer sequence” means in the present context that an active layer sequence applied to the flanks is at least non-functional, i.e. not suitable for generating radiation. In particular, the flanks are no longer provided with material of the active layer sequence at all or are unintentionally contaminated with only minor amounts of material of the active layer sequence.

According to at least one embodiment of the method or its aforementioned embodiments, the third semiconductor layer and the active layer sequence are removed to such an extent that the second semiconductor layer is substantially free of the active layer sequence next to the window.

All semiconductor layers mentioned above, the active layer sequence and, if applicable, the buffer layer are epitaxially grown using conventional metal organic vapor phase epitaxy (MOVPE), for example.

There is an ever-increasing need for micro LEDs (or μLEDs) having sizes <100 μm for a wide range of applications, such as car displays, next-generation TV, micro displays for smartphones and smartwatches, and augmented reality and virtual reality (AR and VR) applications.

μLEDs have so far been produced in practice by combining standard photolithography technology and subsequent dry etching processes on standard LED wafers. However, a dry etching process generally creates surface damage that increases non-radiative recombination, which leads to a reduction in optical performance.

This problem is subordinate for large-area LEDs with dimensions larger than 100 μm and can usually be ignored there.

A major challenge with structure sizes of less than 100 μm is that undesirable surface effects (non-radiative recombination due to defects, etc.) play an increasing role and lead to a drastic efficiency decrease. This problem becomes more severe as the LED dimension decreases and can eventually become a factor that leads to a severe degradation of optical performance.

This problem is particularly acute in the case of the AlGaInP material system already mentioned above, which is used to manufacture red-emitting LEDs.

Overcoming these limitations is a problem underlying the micro semiconductor LED structure and method described herein.

With a micro semiconductor LED structure described herein, the risk of lateral charge carrier transport, i.e., transport within the active layer sequence toward mesa surfaces, can be reduced.

In the present context, “arranged on . . . ” or “apply . . . on” generally means that a further component, for example again one or more semiconductor layer(s), may be provided between the two components concerned, for example semiconductor layers, unless it is expressly stated that the two components arranged or applied on each other are arranged or applied directly on each other.

### BRIEF DESCRIPTION OF THE DRAWINGS

In the following, a micro semiconductor LED structure described herein and a method for producing a micro-semiconductor LED structure described herein are explained in more detail with reference to schematic drawings based on exemplary embodiments and further developments thereof.

Identical reference signs indicate identical elements in the various figures.

As a matter of principle, no scale references are shown in the drawings; rather, individual elements may be shown in exaggerated size for better understanding or recognition.

FIG. 1 shows a schematic representation of a section through a principle μLED having a micro semiconductor LED structure described herein according to a first exemplary embodiment;

FIG. 2 shows a schematic representation of a section through a principle μLED having a micro semiconductor LED structure described herein according to a second exemplary embodiment;

FIG. 3 shows a schematic representation of a section through a principle μLED having a micro semiconductor LED structure described herein according to a third exemplary embodiment;

FIG. 4 shows a schematic representation of a section through a principle μLED having a micro semiconductor LED structure described herein according to a fourth exemplary embodiment; and

FIGS. 5 to 8 show schematic representations of sections through semiconductor layer sequences at various stages of a method for producing a micro semiconductor LED structure according to one of the exemplary embodiments.

### DETAILED DESCRIPTION OF ILLUSTRATIVE EMBODIMENTS

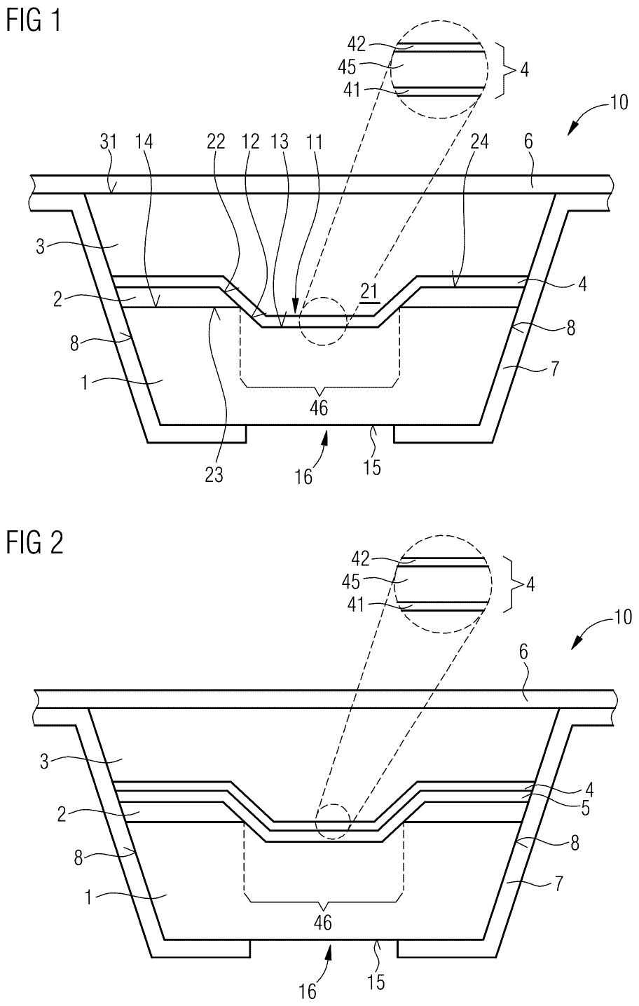

The first exemplary embodiment illustrated in FIG. 1 of a micro semiconductor LED structure 10 described herein comprises an n-type first semiconductor layer 1, a p-type second semiconductor layer 2, an active layer sequence 4 and a p-type third semiconductor layer 3. The second semiconductor layer 2 is arranged on the first semiconductor layer 1. The third semiconductor layer 3 is applied on the active layer sequence 4.

The active layer sequence 4 has an n-type first edge layer 41 facing the first semiconductor layer 1 and a p-type second edge layer 42 facing away from the first semiconductor layer 1. The edge layers can also be called outer barrier layers.

For example, the first to third semiconductor layers 1, 2, 3 and the first and second edge layers 41, 42 are each formed with a semiconductor material based on phosphide compound semiconductor material of the composition (AlₙGa₁₋ₙ)₁₋ₘInₘP, where 0≤n≤1, 0≤m≤1. For example, the first semiconductor layer is formed with (Al_{0.7}Ga_{0.3})_{0.5}In_{0.5}P, the second semiconductor layer is formed with Alo.SIno.5P and the third semiconductor layer is formed with (Al_{0.7}Ga_{0.3})_{0.5}In_{0.5}P. In this case, the n-type conductivity of the first semiconductor layer 1 and the first edge layer 41 is formed, for example, by means of doping with silicon and/or tellurium. The p-type conductivity of the second and third semiconductor layers 2, 3 and the second edge layer 42 is formed, for example, by means of doping with zinc or magnesium.

In order to minimize carrier leakage a material with large bandgap can be used for the p-type second semiconductor layer 2.

The active layer sequence 4 has a radiation-generating layer sequence 45 arranged between the first edge layer 41 and the second edge layer 42. The radiation-generating layer sequence 45 has, for example, at least one pn junction, at least one single quantum well structure (SQW structure), and/or at least one multiple quantum well structure (MQW structure). The pn junction, the single quantum well structure or the multiple quantum well structure is configured to generate visible light. Preferably, the radiation-generating layer sequence is embedded in a p-n junction and contains at least one SQW structure, and/or at least one MQW structure.

In the case of a single or multiple quantum well structure, for example, this structure has between one and 30 periods of alternating quantum wells with Ga_{0.5}In_{0.5}P and barriers with (Al_{0.5}Ga_{0.5})_{0.5}In_{0.5}P each with a thickness in the range of 3 to 15 nm and specifically in the range of 3 to 10 nm.

The second semiconductor layer 2 has at least one window 21 toward the first semiconductor layer 1. The second semiconductor layer 2 has a first main surface 23 facing the first semiconductor layer 1 and a second main surface 24 facing away from the first semiconductor layer 1. The window 21 completely penetrates through the second semiconductor layer 2 from its second main surface 24 toward its first main surface 23, so that the first semiconductor layer 1 is free of the second semiconductor layer 2 in the region of the window 21. The window 21 has flanks 22 from the first main surface 23 toward the second main surface 24.

The first semiconductor layer 1 has a recess 11 in the region of the window 21. The recess 11 has a bottom surface 13 and flanks 12 from the bottom surface 13 to a first main surface 14 of the first semiconductor layer 1 adjacent to the second semiconductor layer 2. The flanks 12 of the recess 11 adjoin the flanks 22 of the window 21 without a step, so that the window 21 continues quasi without a step into the first semiconductor layer 1 to the bottom surface 13 of the recess 11.

The active layer sequence 4 covers the second main surface 24 of the second semiconductor layer 2, the flanks 12 of the recess 11, the flanks 22 of the window 21 and bottom surface 13 of the recess 11.

The first edge layer 41 of the active layer sequence 4 is electrically conductively connected to the first semiconductor layer 1 in the recess 11. The third semiconductor layer 3 is arranged on the active layer sequence 4. The second edge layer 42 of the active layer sequence 4 is electrically conductively connected to the third semiconductor layer 3.

A radiation-generating region 46 of the active layer sequence 4 is, at least substantially, confined to the recess 11. In particular, the radiation-generating region 46 of the active layer sequence 4 is at least substantially confined to the cross-section of the recess lying along the bottom surface of the recess.

A radiation-transmitting p-contact layer 6 is applied on a first main surface 31 of the third semiconductor layer 3 facing away from the active layer sequence 4. The p-contact layer 6 is formed with indium tin oxide (ITO), for example.

Exposed outer surfaces such as the mesa surface 8 of the micro semiconductor LED structure 10 and a second main surface 15 of the first semiconductor layer 1 facing away from the active layer sequence 4 are provided with a passivation layer 7 except for a region 16 for an n-contact at the second main surface 15 of the first semiconductor layer 1. The passivation layer 7 is formed with silicon oxide and/or silicon nitride, for example. The n-contact is formed with gold, for example.

As illustrated in FIG. 2, the second exemplary embodiment differs from the first exemplary embodiment in that a buffer layer 5 is arranged between the second semiconductor layer 2 and the active layer sequence 4 and in the region of the recess 11 between the first semiconductor layer 1 and the active layer sequence 4. The buffer layer 5 serves, for example, to qualitatively increase a growth surface for the growth of the subsequent semiconductor layers, in particular the active layer sequence 4, in particular to increase the crystal quality at the growth surface. The buffer layer 5 is formed, for example, with undoped or slightly n-doped phosphide compound semiconductor material (see above). In particular, the buffer layer 5 is formed with undoped (Al_{0.5}Ga_{0.5})_{0.5}In_{0.5}P and the buffer layer 5 has, for example, a thickness between 5 and 20 nm. Its composition can be for example the same as the material of the barriers. In order to generate a larger band gap in the buffer layer 5 compared to the barriers for example, the Al content can be increased in its aforementioned composition.

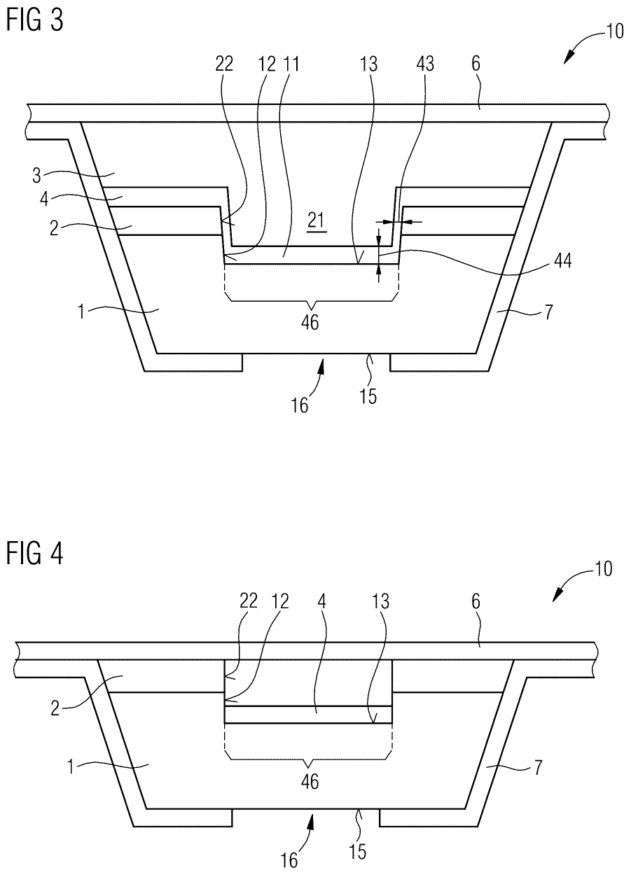

As illustrated in FIG. 3, the third exemplary embodiment differs from the first exemplary embodiment in that the flanks 12, 22 of the recess 11 and the window 21 extend very steeply with respect to a main extension plane of the first semiconductor layer 1. The active layer sequence 4 is formed there significantly thinner than on the bottom surface 13 of the recess 11 and/or may be interrupted there and/or has a different composition there. This can help to further impede a lateral charge carrier transport to the mesa surface 8. Like in the second exemplary embodiment, also in the third exemplary embodiment a buffer layer 5 (not shown in FIG. 3) can be formed between the active layer sequence 4 and the first semiconductor layer 1 and the second semiconductor layer 2, respectively. A material composition of the buffer layer 5 is, for example, as indicated in the second exemplary embodiment.

As illustrated in FIG. 4, the fourth exemplary embodiment differs from the first exemplary embodiment in that the flanks 12 of the recess 11 and the flanks 22 of the window 21 extend substantially perpendicular to a main extension plane of the first semiconductor layer 1.

The meaning of the expression “substantially perpendicular” in the present context has already been explained above in the general part of the description and applies here accordingly.

The flanks 12 of the recess 11 and the flanks 22 of the window 21 are substantially free of the active layer sequence 4. The active layer sequence 4 is present only on a bottom surface 13 of the recess 11 of the first semiconductor layer 1.

The meaning of the expression “substantially free of the active layer sequence” in the present context has already been explained above in the general part of the description and applies here accordingly.

Like in the second exemplary embodiment, also in the fourth exemplary embodiment a buffer layer 5 (not shown in FIG. 4) can be formed between the active layer sequence 4 and the first semiconductor layer 1 and the second semiconductor layer 2, respectively. A material composition of the buffer layer 5 is, for example, as indicated in the second exemplary embodiment.

In the exemplary embodiment illustrated in FIGS. 5 to 8 of a method for producing at least one micro semiconductor LED structure 10 according to one of the exemplary embodiments described above, the n-type first semiconductor layer 1 is first epitaxially grown on a suitable growth substrate (not shown), for example a GaP wafer, and the p-type second semiconductor layer 2 is epitaxially grown on the latter (compare FIG. 5).

The second semiconductor layer 2 has a first main surface 23 facing the first semiconductor layer 1 and a second main surface 24 facing away from the first semiconductor layer 1.

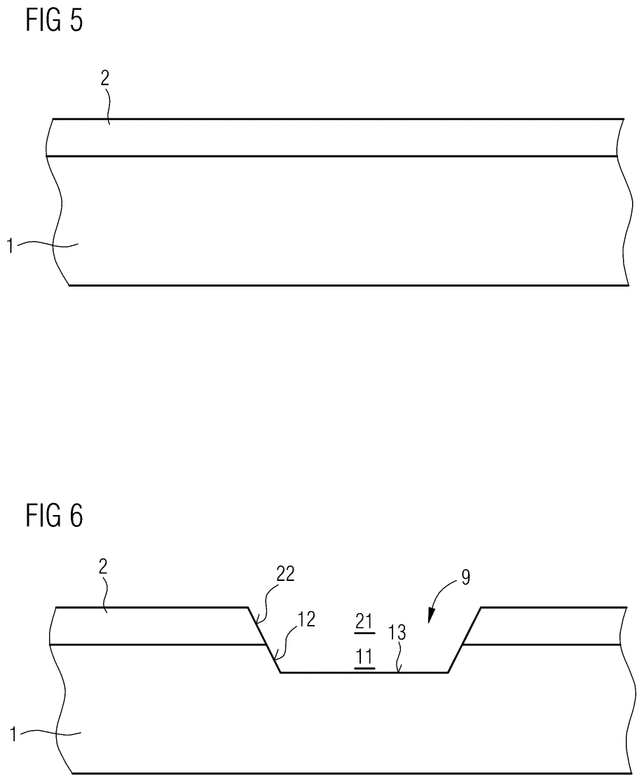

A window 21 toward the first semiconductor layer 1 is later introduced into the second semiconductor layer 2 from the second main surface 24, for example by means of conventional photolithography known to the skilled person and subsequent conventional anisotropic etching known to the skilled person. The window 21 penetrates through the second semiconductor layer 2 up to the first main surface 23, i.e. up to the first semiconductor layer 1. A recess 11 is later formed in the first semiconductor layer 1 through the window 21, for example by means of anisotropic etching, in the region of the first semiconductor layer 1 exposed by the window 21. The recess 11 has a bottom surface 13 and flanks 12. The flanks 12 extend from the bottom surface 13 of the recess 11 toward a first main surface 14 of the first semiconductor layer 1 adjacent to the second semiconductor layer 2. By these two steps a depression 9 is formed in the semiconductor layer sequence of the first semiconductor layer 1 and the second semiconductor layer 2, said depression penetrating through the second semiconductor layer 2 from its second main surface 24 up to the first semiconductor layer 1 and penetrates into the first semiconductor layer 1 to some extent (compare FIG. 6).

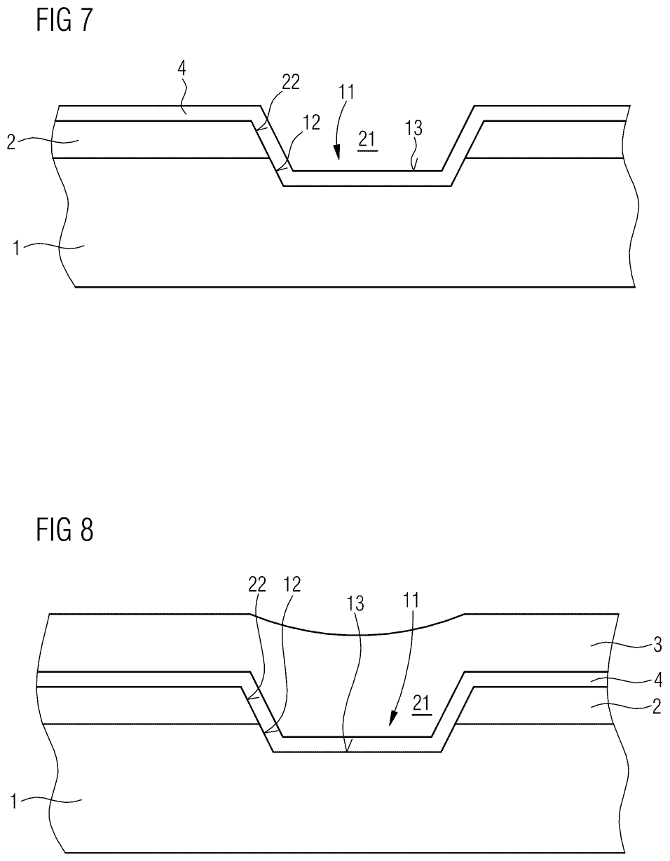

Later, an active layer sequence 4 is epitaxially applied on the first semiconductor layer 1 through the window 21 (see FIG. 7). With the active layer sequence 4 an n-type first edge layer 41 facing the first semiconductor layer 1 and a p-type second edge layer 42 facing away from the first semiconductor layer 1 are epitaxially applied. The layer sequence and material compositions of the various layers such as edge layers, quantum wells and barriers in the active layer sequence 4 are used, for example, in the same way as already described above in connection with the micro semiconductor LED structure 10.

Later, a p-type third semiconductor layer 3 is epitaxially applied on the active layer sequence 4 (see FIG. 8).

In order to increase, for example, the quality of the growth surface, in particular the crystal quality at the growth surface for the subsequent growth of the active layer sequence 4 in the depression 9 after the etching of the depression 9 (see FIG. 6), a buffer layer 5 is epitaxially applied, for example, at least on the bottom surface 13 and the flanks 12, 22 of the recess 11 and of the window 21 (not shown, in this respect reference is made to the second exemplary embodiment and to FIG. 2, in which the buffer layer 5 is illustrated). For example, the buffer layer 5 is epitaxially applied all over in the recess 5 and on the second main surface 24 of the second semiconductor layer 2. The material composition of the buffer layer 5 is, for example, the one already described above in connection with the micro semiconductor LED structure 10. The active layer sequence 4 is later epitaxially applied on the buffer layer 5.

In a method for producing a micro semiconductor LED structure 10 according to the third exemplary embodiment, the window 21 and the recess 11 are provided with flanks 12, 22 extending substantially perpendicular to a main extension plane of the first semiconductor layer 1 (compare FIG. 3). Later, the active layer sequence 4 is applied substantially only on the bottom surface 13 of the first recess 11 and on a second main surface 24 of the second semiconductor layer 2 facing away from the first semiconductor layer 1. The flanks 12, 22 remain substantially free of the active layer sequence 4. The steepness of the flanks 12, 22 is adjusted, for example, by a suitable, sometimes material-dependent choice of the parameters during anisotropic etching.

The expression “substantially free of the active layer sequence” means in the present context that at least no functional active layer sequence 4 is applied to the flanks 12, 22. For example, rather, the flanks 12, 22 are unintentionally contaminated with only minor amounts of material of the active layer sequence 4.

In a method for producing a micro semiconductor LED structure 10 according to the fourth exemplary embodiment, the third semiconductor layer 3 and the active layer sequence 4 are removed, for example, by means of polishing to such an extent that the second semiconductor layer 2 is substantially free of the active layer sequence 4 next to the window (compare FIG. 4).

In the exemplary embodiments of the method described above, the first to third semiconductor layers 1, 2, 3, the active layer sequence 4 and, if applicable, the buffer layer 5 are epitaxially grown, for example, using conventional metal organic vapor phase epitaxy (MOVPE).

The micro semiconductor LED structure described herein and the method described herein are not limited to the exemplary embodiments by the description based on the latter. Rather, the micro semiconductor LED structure described herein and the method described herein include any new feature as well as any combination of features, which in particular includes any combination of features in the patent claims, even if that feature or combination itself is not explicitly stated in the patent claims or embodiments.

1.-16. (canceled)

17. A micro semiconductor LED structure comprising:
a first semiconductor layer of a first conductivity type;
a second semiconductor layer of a second conductivity type, which is arranged on the first semiconductor layer;
an active layer sequence comprising a first edge layer of the first conductivity type facing the first semiconductor layer and a second edge layer of the second conductivity type facing away from the first semiconductor layer; and
a third semiconductor layer of the second conductivity type, which is arranged at least on the active layer sequence,
wherein the first conductivity type and the second conductivity type have opposite doping,
wherein the second semiconductor layer has at least one window, which penetrates through the second semiconductor layer from a side of the second semiconductor layer facing away from the first semiconductor layer toward the first semiconductor layer,
wherein the first semiconductor layer has a recess in a region of the window,
wherein the active layer sequence is arranged at least in the recess,
wherein the first edge layer in the recess is electrically conductively connected to the first semiconductor layer,
wherein the third semiconductor layer is arranged on the active layer sequence at least in the region of the window, and
wherein the second edge layer is electrically conductively connected to the third semiconductor layer, and
wherein the first and the second edge layer are intentionally undoped.

18. The micro semiconductor LED structure according to claim 17, further comprising at least one buffer layer arranged at least in the recess between the active layer sequence and the first semiconductor layer.

19. The micro semiconductor LED structure according to claim 17, wherein flanks of the recess and the window extend obliquely to a main extension plane of the first semiconductor layer such that the recess and the window widen in a direction away from the first semiconductor layer.

20. The micro semiconductor LED structure according to claim 17, wherein flanks of the recess and the window extend substantially perpendicular to a main extension plane of the first semiconductor layer.

21. The micro semiconductor LED structure according to claim 19, wherein the flanks of the recess and the window are substantially free of active layer sequence.

22. The micro semiconductor LED structure according to claim 19, wherein the active layer sequence extends, starting from a bottom surface of the recess, over the flanks of the recess and the window to a side of the second semiconductor layer facing away from the first semiconductor layer.

23. The micro semiconductor LED structure according to claim 22, wherein a thickness of the active layer sequence in a region of the flanks is smaller than a thickness of the active layer sequence in a region along the bottom surface of the recess.

24. The micro semiconductor LED structure according to claim 17, wherein at least the active layer sequence comprises a semiconductor material based on phosphide compound semiconductor material.

25. The micro semiconductor LED structure according to claim 17, wherein the first semiconductor layer and the second semiconductor layer form a pn-junction and the active layer sequence penetrates the pn-junction.

26. The micro semiconductor LED structure according to claim 17, wherein, in plan view of the active layer sequence, outer parts of the active layer sequence around a radiation-generating region lying between the radiation-generating region of the active layer sequence and mesa edges of the micro semiconductor LED structure are embedded between the second semiconductor layer and the third semiconductor layer of the second conductivity type.

27. A method for producing a micro semiconductor LED structure, the method comprising:
providing a first semiconductor layer of a first conductivity type;
applying a second semiconductor layer of a second conductivity type on the first semiconductor layer;
forming a window through the second semiconductor layer up to the first semiconductor layer;
forming a recess in the first semiconductor layer in a region of the first semiconductor layer exposed by the window;
applying an active layer sequence comprising a first edge layer of the first conductivity type facing the first semiconductor layer and a second edge layer of the second conductivity type facing away from the first semiconductor layer through the window on the first semiconductor layer, wherein the first and second edge layers are intentionally undoped; and
applying a third semiconductor layer of the second conductivity type on the active layer sequence.

28. The method according to claim 27, wherein the first semiconductor layer and the first edge layer are doped opposite to the second semiconductor layer, the third semiconductor layer and the second edge layer.

29. The method according to claim 27, wherein the window and the recess are produced by photolithography followed by anisotropic etching.

30. The method according to claim 27, further comprising applying a buffer layer at least on a bottom surface of the recess, on which buffer layer the active layer sequence is later applied.

31. The method according to claim 27, wherein the window and the recess are provided with flanks extending substantially perpendicular to a main extension plane of the first semiconductor layer, and the active layer sequence is applied only on a bottom surface of the first semiconductor layer and on a main surface of the second semiconductor layer facing away from the first semiconductor layer.

32. The method according to claim 27, further comprising removing the third semiconductor layer and the active layer sequence to such an extent that the second semiconductor layer is freed from the active layer sequence next to the window.

33. A micro semiconductor LED structure comprising:
a first semiconductor layer of a first conductivity type;
a second semiconductor layer of a second conductivity type, which is arranged on the first semiconductor layer;
an active layer sequence comprising a first edge layer of the first conductivity type facing the first semiconductor layer and a second edge layer of the second conductivity type facing away from the first semiconductor layer; and
a third semiconductor layer of the second conductivity type, which is arranged at least on the active layer sequence,
wherein the first conductivity type and the second conductivity type have opposite doping,
wherein the second semiconductor layer has at least one window which penetrates through the second semiconductor layer from a side of the second semiconductor layer facing away from the first semiconductor layer toward the first semiconductor layer,
wherein the first semiconductor layer has a recess in a region of the window,
wherein the active layer sequence is arranged at least in the recess,
wherein the first edge layer in the recess is electrically conductively connected to the first semiconductor layer,
wherein the third semiconductor layer is arranged on the active layer sequence at least in the region of the window,
wherein the second edge layer is electrically conductively connected to the third semiconductor layer,
wherein the first semiconductor layer and the second semiconductor layer form a pn-junction and the active layer sequence penetrates the pn-junction, and
wherein the micro semiconductor LED structure does not include a growth substrate.
